(19) United States
(12) Patent Application Publication
(10) Pub. No.: US 2026/0107710 A1
(43) Pub. Date: Apr. 16, 2026

(54) BORON CATALYZED DIELECTRIC FILM DEPOSITIONS

(71) Applicant: Applied Materials, Inc., Santa Clara, CA (US)

(72) Inventors: Lakmal C. KALUTARAGE, San Jose, CA (US); Mark J. SALY, Santa Clara, CA (US); Bhaskar Jyoti BHUYAN, San Jose, CA (US); Lisa J. ENMAN, Sunnyvale, CA (US); SeyedMahmoud HOSSEINI, Santa Clara, CA (US); Arkaprava DAN, San Jose, CA (US); Chi-Chou LIN, San Jose, CA (US)

(21) Appl. No.: 18/916,353

(22) Filed: Oct. 15, 2024

(51) Int. Cl. H01L 21/02; C23C 16/44

(52) U.S. Cl. CPC H10P 14/6682; C23C 16/4408

(57) ABSTRACT

The present disclosure provides methods of depositing dielectric films in processing chambers. The methods include disposing a substrate on a susceptor disposed within a processing chamber. A first precursor-containing gas mixture is provided into the processing chamber. The first precursor-containing gas mixture includes a boron-containing precursor and a carrier gas selected from the group consisting of argon, nitrogen, and helium. A second precursor-containing gas mixture is provided into the processing chamber.

### FIELD

The present disclosure generally relates to low k dielectric films disposed over a substrate, and, more particularly, relates to depositing a boron catalyzed low k dielectric films over a substrate.

### BACKGROUND

The development of semiconductor devices continuously demands smaller dimensions, larger data capacity, and faster processing speed. To meet the performance demands of these semiconductor devices, insulating layers that separate other layers need to have a low dielectric constant, k, (less than three (3.5)), a low wet etch rate in DHF (less than 3 Å/min), resistance to ashing plasma, and a thermal stability of greater than 500° C. Indeed, a conformality of about 100% of the low k film is desired.

Conventional approaches to deposit low k films include atomic layer deposition (ALD), chemical vapor deposition (CVD), and plasma enhanced ALD (PEALD). Unfortunately, each of these processes results in reduced conformality, and/or composition conformality due to plasma non-uniformity, respectively. Plasma and/or ozone may be employed to overcome this self-limiting growth, however, the conformality of the low k film is reduced. Moreover, a reduction in composition conformality due to plasma non-uniformity leads to reduced and/or no carbon or nitrogen in features, e.g., trenches, of a substrate.

Accordingly, there is a need for an improved precursor and method for forming a low k film on a substrate.

### SUMMARY

In an embodiment, the present disclosure provides methods of depositing dielectric films in processing chambers. The methods include disposing a substrate on a susceptor disposed within a processing chamber. A first precursor-containing gas mixture is provided into the processing chamber. The first precursor-containing gas mixture includes a boron-containing precursor and a carrier gas selected from the group consisting of argon, nitrogen, and helium. A second precursor-containing gas mixture is provided into the processing chamber.

In another embodiment, the present disclosure provides methods of depositing dielectric films in processing chambers. The methods include disposing a substrate on a susceptor disposed within a processing chamber. A first precursor-containing gas mixture and a second precursor-containing gas mixture is provided into the processing chamber in the presence of a plasma. The first precursor-containing gas mixture includes a boron-containing precursor and the second precursor-containing gas mixture includes a silicon-containing precursor gas.

In another embodiment, the present disclosure provides methods of depositing dielectric films in processing chambers. The methods include disposing a substrate on a susceptor disposed within a processing chamber. A first precursor-containing gas mixture is provided into the processing chamber at a first flow rate. The first precursor-containing gas mixture includes trimethyl borate, trimethylborane, or diborane and a carrier gas selected from the group consisting of argon, nitrogen, and helium. A second precursor-containing gas mixture is provided into the processing chamber at a second flow rate. A ratio of the first flow rate to the second flow rate is about 1:1 to about 1:30.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a schematic top view of a processing system, according to an embodiment of the present disclosure.

FIG. 2 illustrates a schematic cross-sectional view of a processing chamber for depositing a dielectric constant film on a substrate, according to an embodiment of the present disclosure.

FIG. 3 illustrates a method for forming a low k dielectric film in a processing chamber, according to an embodiment of the present disclosure.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In an embodiment, the present disclosure provides boron catalyzed low dielectric constant (k) films, and methods for forming boron catalyzed low k films having a low dielectric constant (k), e.g., below 3.5, a low wet etch rate in DHF, e.g., less than 3 Å/min, resistance to ashing plasma, and a thermal stability of greater than 500° C. Advantageously, the present disclosure can provide dielectric films, such as SiCON, SiCO, SiO, SiN, SiON, or a combination thereof, by catalyzing thermal atomic layer deposition (ALD) using a catalyst precursor without increasing the dielectric constant to greater than 4. Additionally, and advantageously, the catalyst precursor acts as a lewis acid, thereby activating the dielectric films deposited over the substrate to allow for additional thermal ALD reactions between silicon-containing precursors to be deposited and one or more surface bonds of the dielectric film.

Many of the details, dimensions, angles and other features shown in the Figures are merely illustrative of particular embodiments. Accordingly, other embodiments can have other details, components, dimensions, angles and features without departing from the spirit or scope of the present disclosure. In addition, further embodiments of the disclosure can be practiced without several of the details described below.

A “substrate,” “substrate surface,” or the like, as used herein, refers to any substrate or material surface formed on a substrate upon which processing is performed. For example, a substrate surface on which processing can be performed include, but are not limited to, materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate (or otherwise generate or graft target chemical moieties to impart chemical functionality), anneal and/or bake the substrate surface. In addition to processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface. What a given substrate surface comprises will depend on what materials are to be deposited, as well as the particular chemistry used.

As used in this specification and the appended claims, the terms “precursor compound,” “precursor gas,” “precursor species,” “precursor,” “precursor gas,” and the like are used interchangeably to include at least a substance with a species capable of forming a material on the substrate surface in a surface reaction.

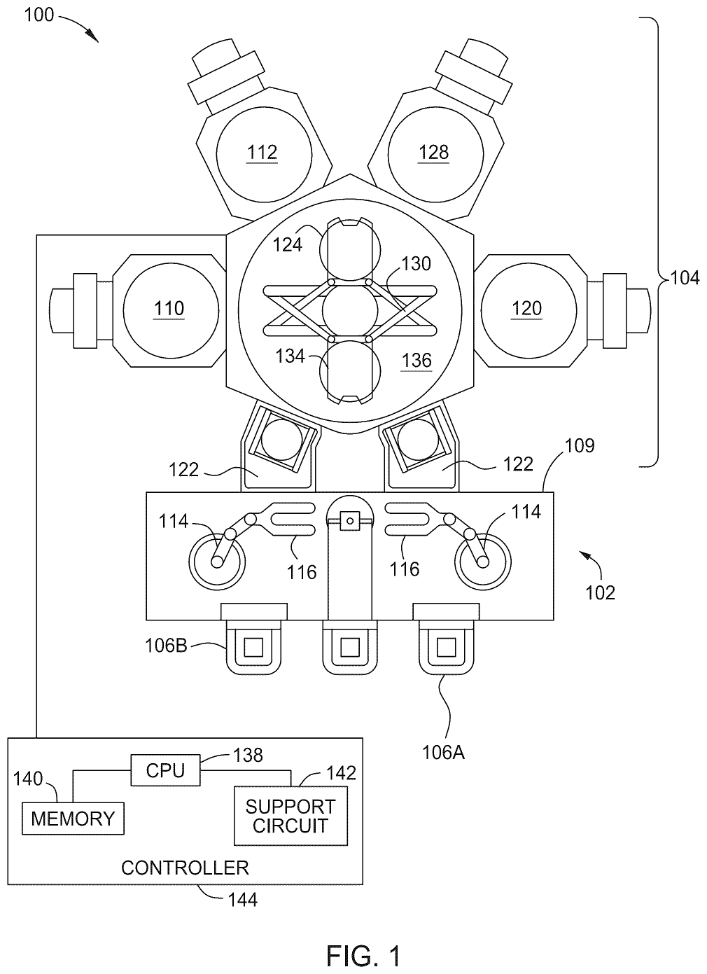

FIG. 1 illustrates a schematic top view of a processing system 100 for depositing a dielectric film on a substrate, according to one or more embodiments. The processing system 100 is configured to implement the method to form a dielectric film according to various embodiments of the present disclosure. The processing system 100 includes a processing platform 104 coupled with a factoring interface 102 and a controller 144. In one or more embodiments, the processing system 100 may be adapted for use in a CENTURA© integrated processing system provided by Applied Materials, Inc., located in Santa Clara, California. It is contemplated that other processing systems (including those from other manufacturers) may be adapted to benefit from the present disclosure.

The processing platform 104 includes a plurality of processing chambers 110, 112, 120, 128, one or more load lock chambers 122, and a transfer chamber 136 that is coupled to the one or more load lock chamber 122. The plurality of processing chamber 110 may include an atomic layer deposition (ALD) chamber, a chemical vapor deposition (CVD) chamber, a plasma enhanced chemical vapor deposition (PECVD) chamber, an epitaxy (EPI) chamber, a rapid thermal processing (RTP) chamber, a reactive ion etching (RIE) chamber, or other suitable chamber. The transfer chamber 136 can be maintained under vacuum, or can be maintained at an ambient (e.g., atmospheric) pressure. Two load lock chambers 122 are shown in FIG. 1.

Each of the load lock chambers 122 has a first port interfacing with the factory interface 102 and a second port interfacing with the transfer chamber 136. The transfer chamber 136 has a vacuum robot 130 disposed therein. The vacuum robot 130 has one or more blades 134 (two are shown in FIG. 1) capable of transferring the substrates 124 between the load lock chambers 122 and the processing chambers 110, 112, 120, and 128.

The factory interface 102 is coupled to the transfer chamber 136 through the load lock chambers 122. In one or more embodiments, the factory interface 102 includes at least one docking station 109 and at least one factory interface robot 114 to facilitate the transfer of substrates 124. The docking station 109 is configured to accept one or more front opening unified pods (FOUPs). Two FOUPS 106A, 106B are shown in the implementation of FIG. 1. The factory interface robot 114 having a blade 116 disposed on one end of the robot 114 is configured to transfer one or more substrates from the FOUPS 106A, 106B, through the load lock chambers 122, to the processing platform 104 for processing. Substrates being transferred can be stored at least temporarily in the load lock chambers 122.

The controller 144 is coupled to the processing system 100 and is used to control processes and methods, such as the operations of the methods described herein (for example the operations of the methods as described in other parts of the present disclosure). The controller 144 includes a central processing unit (CPU) 138, a memory 140 containing instructions, and support circuits 142 for the CPU. The controller 144 controls various items directly, or via other computers and/or controllers.

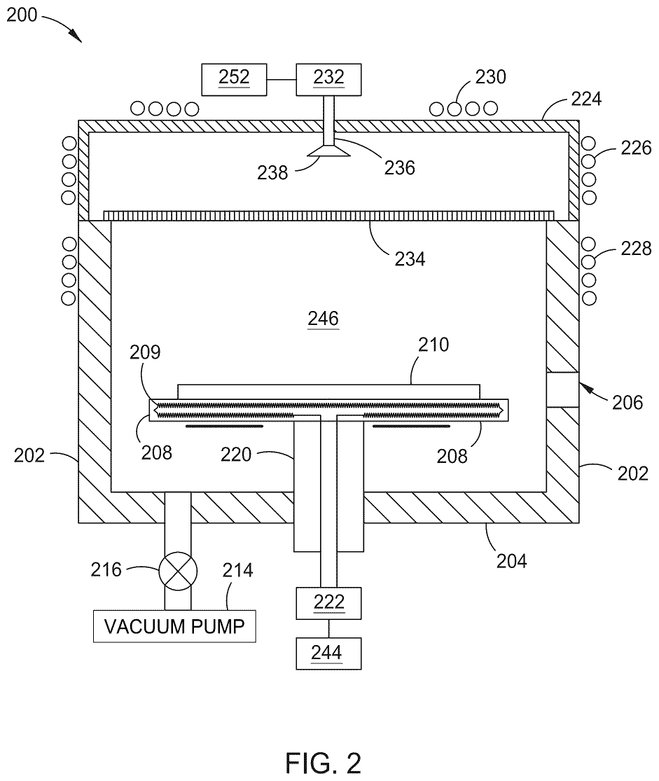

FIG. 2 illustrates a processing chamber 200, according to an embodiment. The processing chamber 200 may be an ALD chamber, a CVD chamber, or a PECVD chamber configured to deposit a dielectric film on a substrate 210 according to various embodiment of the present disclosure. At least one of the processing chambers 110, 112, 120, 128 of FIG. 1 may be configured as the processing chamber 200. The processing chamber 200 in FIG. 2 includes side walls 202, a bottom 204, a chamber lid 224, and a lower wall liner 248. The chamber lid 224, the side walls 202, and the bottom 204 together enclose a processing region 246. A susceptor 208 is disposed in the processing region 246 and supports the substrate 210 thereon during processing. The side walls 202 include a plurality of ports 206 for transferring the substrate 210 in or out of the processing chamber 200.

The processing chamber 200 further includes a vacuum pump 214 and a plurality of gas sources 232 configured to provide a plurality of process gases into the processing chamber 200. The plurality of process gases may include a first precursor gas, a second precursor gas, an inert gas, an oxidizing gas, a purge gas, or a combination thereof. A remote plasma source 252 may be coupled with the gas sources 232 and configured to energize the process gas independently or energize a mixture of two or more of the process gases, e.g., the first precursor gas and the second precursor gas. The energized process gas is provided to the process chamber 200 via a top baffle 236. The vacuum pump 214 is coupled to the processing chamber 200 and configured to adjust the vacuum level within the process region 246 via a valve 216. The vacuum pump 214 is also configured to evacuate spent gases from the processing chamber 200.

The processing chamber 200 may include a gas plenum 238 contained between the lid 224 and a showerhead 234. The gas showerhead 234 includes a plurality of conduits that allow the process gases to flow through.

The processing chamber 200 includes one or more plasma sources 226, 228, 230 disposed at various locations of the processing chamber 200 to energize the process gases. As shown in FIG. 2, a plasma source 230 may be disposed at a top surface of the lid 224, and/or another plasma source 226 is disposed around the side walls of the lid 224. The plasma sources 230 and 226 are operable to energize the process gases above the showerhead 234, e.g., within the gas plenum 238. Another plasma source 228 may be disposed along side walls 202 and is operable to energize the process gases between the showerhead 234 and the susceptor 208. The plasma sources 252, 230, 226, and 228 can be controlled independently or collectively by the controller 114 depicted in FIG. 1.

The susceptor 208 may be part of a substrate support assembly 220, which includes an electrode 209 coupled with one or more power sources 222 and 244. The electrode 209 may be configured to heat the susceptor 208 and/or chuck the substrate 210 on the susceptor 208.

The controller 144 is configured to control the plurality of gas sources 232, the plurality of plasma sources 226, 228, and 230, the vacuum pump 214, and the plurality of the power sources 222 and 224. The control 144 is capable of controlling the flow rate of the process gases, the temperature of the susceptor, the pressure level of the processing chamber, and the RF power delivered into the processing chamber.

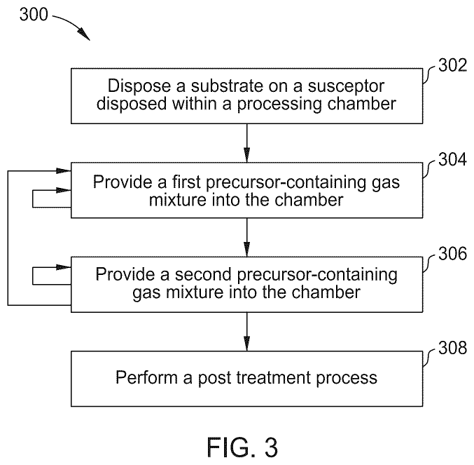

FIG. 3 illustrates a method 300 for depositing a dielectric film on a substrate, according to an embodiment of the present disclosure. Instructions for the method 300 may be stored in the memory 140 of the controller 144, that when executed by the CPU 138, cause the process chamber 200 to perform the operations of the method 300.

At operation 302, a substrate, such as a substrate 210 shown in FIG. 2, is disposed in the processing chamber 200. The substrate 210 is positioned on the susceptor 208 and held by a chucking electrode. The substrate 210 may include a material such as crystalline silicon (e.g., Si(100) or Si(111)), silicon oxide, strained silicon, silicon germanium, doped or undoped polysilicon, doped or undoped silicon substrates and patterned or non-patterned substrates silicon on insulator (SOI), carbon doped silicon oxides, silicon nitride, doped silicon, germanium, gallium arsenide, glass, sapphire. The substrate 210 may include one or more features, e.g., trenches, vias holes, cavities, or a combination thereof. The dielectric film of one or more embodiments may be formed on any surface or any portion of the substrate 210, e.g., within or over one or more trenches, vias, holes, cavities, or a combination thereof.

At operation 304, a first precursor-containing gas mixture is flowed into the processing volume. The first precursor-containing gas mixture may be introduced into the processing volume while maintaining a pressure of about 10 mTorr to about 50 Torr and a temperature of about 25° C. to about 600° C. The precursor-containing gas mixture may include one or more boron-containing precursor gases. The boron-containing precursors can include tris(dimethylamino)borane (TDMAB), tris(ethylmethylamino)borane (TEMAB), trimethyl borate, triethyl borate, triisopropyl borate, diborane, borazine, triethylborane, trimethylborane, borane dimethylamine, borane diethylamine, borane trimethylamine, borane triethylamine, borane ammonia, boron trichloride, boron tribromide, boron trifluoride, or a combination thereof.

A first flow rate of the first precursor-containing gas mixture may be between about 50 sccm to about 10,000 sccm. In an embodiment, the precursor gas may be provided into the processing chamber continuously or in a pulsing manner. In an embodiment, the first precursor-containing gas mixture may additionally include an oxidizing gas, such as O₂, N₂O, NO₂, CO, CO₂, or other oxidizing gas. In some embodiments, a carrier gas, such as argon (Ar), helium (He), nitrogen (N₂), may be supplied with the first precursor-containing gas mixture and/or following the first precursor-containing gas mixture into the processing volume. The carrier gas may be introduced to the processing chamber at a flow rate of about 100 sccm to about 10,000 sccm.

Additionally, a variety of other processing gases may be added to the precursor-containing gas mixture to modify properties of the dielectric film. In one or more embodiments, the other processing gases may be reactive gases, such as hydrogen (H₂), ammonia (NH₃), a mixture of hydrogen (H₂) and nitrogen (N₂), or combinations thereof. The addition of H₂ and/or NH₃ may be used to control the hydrogen ratio of the deposited dielectric film.

Optionally, operation 304 can include a first purge process. The first purge process can include introducing the carrier gas to the processing chamber, in which the first precursor-containing gas mixture is not introduced into the processing chamber. The first purge process can include flowing the carrier gas to the processing chamber at a flow rate of about 100 sccm to about 10,000 sccm.

Optionally, operation 304 can include introducing a first co-reactant to the processing chamber. The first co-reactant can include one or more hydrogen-containing reactants. The one or more hydrogen-containing reactants can include water, ammonia, primary alcohols, secondary alcohols, carboxylic acids, aldehydes, hydrazines, alkyl amines, or a combination thereof. For example, the one or more hydrogen-containing reactants can include methanol, ethanol, isopropyl alcohol, or combinations thereof. As a further example, the one or more hydrogen-containing reactants can include acetic acid, formic acid, propionic acid, or combinations thereof. As a further example, the one or more hydrogen-containing reactants can include acetaldehyde, formaldehyde, or combinations thereof. As a further example, the one or more hydrogen-containing reactants can include primary amines, secondary amines, tertiary amines, or combinations thereof.

Optionally, operation 304 can include a second purge process. The second purge process can include introducing the carrier gas to the processing chamber following the co-reactant, in which the first precursor-containing gas mixture and/or the co-reactant is not introduced into the processing chamber. The second purge process can include flowing the carrier gas to the processing chamber at a flow rate of about 100 sccm to about 10,000 sccm.

In some embodiments, operation 304 may be repeated for about 1 to about 1,000 cycles. For example, operation 304 can include a first cycle of flowing the first precursor-containing gas mixture into the processing chamber, performing a first purge process, and introducing a first co-reactant precursor. The first cycle can be repeated for 2 to 1000 cycles. As a further example, operation 304 can include an alternate cycle of flowing the first precursor-containing gas mixture into the processing chamber, performing a first purge process, introducing a first co-reactant precursor, and performing a second purge process. The alternate cycle can be repeated for 2 to 1000 cycles.

At operation 306, a second precursor-containing gas mixture is flowed into the processing volume. The first precursor-containing gas mixture may be introduced into the processing volume while maintaining a pressure of about 10 mTorr to about 50 Torr and a temperature of about 25° C. to about 600° C. The second precursor-containing gas mixture may include one or more silicon-containing precursor gases, such as Si-based precursor gases containing Si, O, C, and H. In some embodiments, the silicon-containing precursor gases include a silane, ring type siloxane, a linear type silane having a Si—O link, a linear type silane having a Si—C link, and a linear type siloxane having a Si—O—Si link. For example, the silicon-containing precursor can be represented by formula (I):

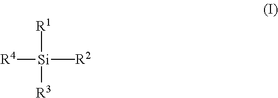

where Si represents a silicon atom and C represents a carbon atom. Each of R¹-R⁴ may independently be hydrogen (H), substituted or unsubstituted C₁-C₁₀ alkyl, substituted or unsubstituted C₁-C₁₀ alkylene, substituted or unsubstituted C₁-C₁₀ alkynylene, substituted or unsubstituted C₁-C₁₀ alkyoxy, substituted or unsubstituted C₁-C₁₀ alkylamine, halide, e.g., chlorine, bromine, or iodine, substituted or unsubstituted C₁-C₁₀ alkyloxyamine, or substituted or unsubstituted C₁-C₁₀ alkyl sulfonamide. In an embodiment, the substituted C₁-C₁₀ alkyl substituted C₁-C₁₀ alkylene, substituted C₁-C₁₀ alkynylene, substituted C₁-C₁₀ alkyoxy, substituted C₁-C₁₀ alkylamine, substituted C₁-C₁₀ alkyloxyamine, and/or substituted C₁-C₁₀ alkyl sulfonamide may include one or more of an oxygen atom, a nitrogen atom, a sulfur atom, a chlorine atom, a fluorine atom, or a combination thereof. In some embodiments, each of R¹-R⁴ may be independently selected from the group consisting of methyl (Me), methoxy (OMe), ethyl (Et), ethoxy (OEt), isopropyl (iPr), isoproproxy (OiPr), and tert-butyl (tBu). For example, the silicon-containing precursor can be represented by Si(OCH₃)₄, Si(CH₃)(OtBu)₂, or combinations thereof.

As a further example, the silicon-containing precursor can be represented by formula (II):

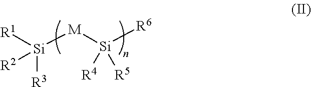

where Si represents a silicon atom and C represents a carbon atom. M is carbon or oxygen. n is an integer of 1 to 5. Each of R¹-R⁶ may independently be hydrogen (H), substituted or unsubstituted C₁-C₁₀ alkyl, substituted or unsubstituted C₁-C₁₀ alkylene, substituted or unsubstituted C₁-C₁₀ alkynylene, substituted or unsubstituted C₁-C₁₀ alkyoxy, substituted or unsubstituted C₁-C₁₀ alkylamine, halide, e.g., chlorine, bromine, or iodine, substituted or unsubstituted C₁-C₁₀ alkyloxyamine, or substituted or unsubstituted C₁-C₁₀ alkyl sulfonamide. In an embodiment, the substituted C₁-C₁₀ alkyl substituted C₁-C₁₀ alkylene, substituted C₁-C₁₀ alkynylene, substituted C₁-C₁₀ alkyoxy, substituted C₁-C₁₀ alkylamine, substituted C₁-C₁₀ alkyloxyamine, and/or substituted C₁-C₁₀ alkyl sulfonamide may include one or more of an oxygen atom, a nitrogen atom, a sulfur atom, a chlorine atom, a fluorine atom, or a combination thereof. In some embodiments, each of R¹-R⁶ may be independently selected from the group consisting of methyl (Me), methoxy (OMe), ethyl (Et), ethoxy (OEt), isopropyl (iPr), isoproproxy (OiPr), and tert-butyl (tBu). For example, the silicon-containing precursor can be represented by (NMe₂)₃Si—CH₂—Si(NMe₂)₃.

As a further example, the silicon-containing precursor can be represented by formula (III):

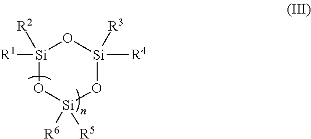

where Si represents a silicon atom and C represents a carbon atom. n is an integer of 1 to 5. Each of R¹-R⁶ may independently be hydrogen (H), substituted or unsubstituted C₁-C₁₀ alkyl, substituted or unsubstituted C₁-C₁₀ alkylene, substituted or unsubstituted C₁-C₁₀ alkynylene, substituted or unsubstituted C₁-C₁₀ alkyoxy, substituted or unsubstituted C₁-C₁₀ alkylamine, halide, e.g., chlorine, bromine, or iodine, substituted or unsubstituted C₁-C₁₀ alkyloxyamine, or substituted or unsubstituted C₁-C₁₀ alkyl sulfonamide. In an embodiment, the substituted C₁-C₁₀ alkyl substituted C₁-C₁₀ alkylene, substituted C₁-C₁₀ alkynylene, substituted C₁-C₁₀ alkyoxy, substituted C₁-C₁₀ alkylamine, substituted C₁-C₁₀ alkyloxyamine, and/or substituted C₁-C₁₀ alkyl sulfonamide may include one or more of an oxygen atom, a nitrogen atom, a sulfur atom, a chlorine atom, a fluorine atom, or a combination thereof. In some embodiments, each of R¹-R⁶ may be independently selected from the group consisting of methyl (Me), methoxy (OMe), ethyl (Et), ethoxy (OEt), isopropyl (iPr), isoproproxy (OiPr), and tert-butyl (tBu).

As a further example, the silicon-containing precursor can be represented by formula (IV):

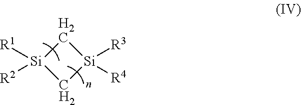

where Si represents a silicon atom and C represents a carbon atom. n is an integer of 1 to 5. Each of R¹-R⁴ may independently be hydrogen (H), substituted or unsubstituted C₁-C₁₀ alkyl, substituted or unsubstituted C₁-C₁₀ alkylene, substituted or unsubstituted C₁-C₁₀ alkynylene, substituted or unsubstituted C₁-C₁₀ alkyoxy, substituted or unsubstituted C₁-C₁₀ alkylamine, halide, e.g., chlorine, bromine, or iodine, substituted or unsubstituted C₁-C₁₀ alkyloxyamine, or substituted or unsubstituted C₁-C₁₀ alkyl sulfonamide. In an embodiment, the substituted C₁-C₁₀ alkyl substituted C₁-C₁₀ alkylene, substituted C₁-C₁₀ alkynylene, substituted C₁-C₁₀ alkyoxy, substituted C₁-C₁₀ alkylamine, substituted C₁-C₁₀ alkyloxyamine, and/or substituted C₁-C₁₀ alkyl sulfonamide may include one or more of an oxygen atom, a nitrogen atom, a sulfur atom, a chlorine atom, a fluorine atom, or a combination thereof. In some embodiments, each of R¹-R⁴ may be independently selected from the group consisting of methyl (Me), methoxy (OMe), ethyl (Et), ethoxy (OEt), isopropyl (iPr), isoproproxy (OiPr), and tert-butyl (tBu).

As a further example, the silicon-containing precursor can be represented by formula (V):

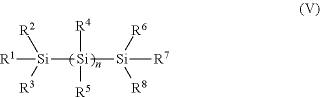

where Si represents a silicon atom and C represents a carbon atom. n is an integer of 0 to 5. Each of R¹-R⁸ may independently be hydrogen (H), substituted or unsubstituted C₁-C₁₀ alkyl, substituted or unsubstituted C₁-C₁₀ alkylene, substituted or unsubstituted C₁-C₁₀ alkynylene, substituted or unsubstituted C₁-C₁₀ alkyoxy, substituted or unsubstituted C₁-C₁₀ alkylamine, halide, e.g., chlorine, bromine, or iodine, substituted or unsubstituted C₁-C₁₀ alkyloxyamine, or substituted or unsubstituted C₁-C₁₀ alkyl sulfonamide. In an embodiment, the substituted C₁-C₁₀ alkyl substituted C₁-C₁₀ alkylene, substituted C₁-C₁₀ alkynylene, substituted C₁-C₁₀ alkyoxy, substituted C₁-C₁₀ alkylamine, substituted C₁-C₁₀ alkyloxyamine, and/or substituted C₁-C₁₀ alkyl sulfonamide may include one or more of an oxygen atom, a nitrogen atom, a sulfur atom, a chlorine atom, a fluorine atom, or a combination thereof. In some embodiments, each of R¹-R⁸ may be independently selected from the group consisting of methyl (Me), methoxy (OMe), ethyl (Et), ethoxy (OEt), isopropyl (iPr), isoproproxy (OiPr), and tert-butyl (tBu).

A second flow rate of the second precursor-containing gas mixture may be between about 50 sccm to about 10,000 sccm. In an embodiment, a ratio of the first flow rate, e.g., flow rate of the first precursor-containing gas mixture, to the second flow rate, e.g., flow rate of the second precursor-containing gas mixture, can be about 1:1 to about 1:30 of the first flow rate to the second flow rate. Without being bound by theory, a ratio of about 1:1 to about 1:30 of the first flow rate to the second flow rate can allow for improved thermal ALD due to the polarization of the surface layer bonds via activation of the silicon atoms of the precursors. For example, a ratio of a ratio of about 1:1 to about 1:30 of the first flow rate to the second flow rate can increase the polarity of an O—H surface bond of B—O—Si—O—H, a N-Me surface bond of B—O—Si—N-Me₂, and/or a Si—Cl surface bond of B—O—Si—Cl to promote thermal ALD reactions, thereby preventing self-limiting growth.

In an embodiment, the second precursor-containing gas mixture may be provided into the processing chamber continuously or in a pulsing manner. In an embodiment, the second precursor-containing gas mixture may additionally include an oxidizing gas, such as O₂, N₂O, NO₂, CO, CO₂, or other oxidizing gas. In some embodiments, a carrier gas, such as argon (Ar), helium (He), nitrogen (N₂), may be supplied with the second precursor-containing gas mixture and/or following the second precursor-containing gas mixture into the processing volume. The carrier gas may be introduced to the processing chamber at a flow rate of about 100 sccm to about 10,000 sccm.

Additionally, a variety of other processing gases may be added to the second precursor-containing gas mixture to modify properties of the dielectric film. In one or more embodiments, the other processing gases may be reactive gases, such as hydrogen (H₂), ammonia (NH₃), a mixture of hydrogen (H₂) and nitrogen (N₂), or combinations thereof. The addition of H₂ and/or NH₃ may be used to control the hydrogen ratio of the deposited dielectric film.

Optionally, operation 306 can include a third purge process. The third purge process can include introducing the carrier gas to the processing chamber, in which the second precursor-containing gas mixture is not introduced into the processing chamber. The third purge process can include flowing the carrier gas to the processing chamber at a flow rate of about 100 sccm to about 10,000 sccm.

Optionally, operation 306 can include introducing a second co-reactant to the processing chamber. The second co-reactant can include one or more hydrogen-containing reactants. The one or more hydrogen-containing reactants can include water, ammonia, primary alcohols, secondary alcohols, carboxylic acids, aldehydes, hydrazines, alkyl amines, or a combination thereof. For example, the one or more hydrogen-containing reactants can include methanol, ethanol, isopropyl alcohol, or combinations thereof. As a further example, the one or more hydrogen-containing reactants can include acetic acid, formic acid, propionic acid, or combinations thereof. As a further example, the one or more hydrogen-containing reactants can include acetaldehyde, formaldehyde, or combinations thereof. As a further example, the one or more hydrogen-containing reactants can include primary amines, secondary amines, tertiary amines, or combinations thereof.

Optionally, operation 306 can include a fourth purge process. The fourth purge process can include introducing the carrier gas to the processing chamber following the second co-reactant, in which the second precursor-containing gas mixture and/or the second co-reactant is not introduced into the processing chamber. The fourth purge process can include flowing the carrier gas to the processing chamber at a flow rate of about 100 sccm to about 10,000 sccm.

In some embodiments, operation 306 may be repeated for about 1 to about 1,000 cycles. For example, operation 306 can include a first cycle of flowing the second precursor-containing gas mixture into the processing chamber, performing a second purge process, and introducing a second co-reactant precursor. The first cycle can be repeated for 2 to 1000 cycles. As a further example, operation 306 can include an alternate cycle of flowing the second precursor-containing gas mixture into the processing chamber, performing a third purge process, introducing a second co-reactant precursor, and performing a fourth purge process. The alternate cycle can be repeated for 2 to 1000 cycles.

In some embodiments, operations 304 and 306 may be repeated. In some embodiments, operations 304 and 306 may be repeated for about 1 to about 1,000 cycles.

In an embodiment, operations 304 and 306 may be performed concurrently, and in the presence of a non-oxidizing plasma in the processing chamber, e.g., an argon-based plasma, a nitrogen-based plasma, a helium-based plasma, an ammonium-based plasma, and/or a hydrogen-based plasma. The non-oxidizing plasma may be energized before the precursor is delivered into the processing chamber. Alternatively, the non-oxidizing plasma may be energized after the precursor is delivered into the processing chamber. Without being bound by theory, a non-oxidizing plasma may allow for reduced oxidation of the substrate, thereby maintaining reduced resistivity of the substrate. Moreover, due to the use of the first precursor gas mixture, including a boron containing precursor, the non-oxidizing plasma may be used while increasing reactivity with the silicon-based precursor compounds, thereby increasing deposition rate of the low k film.

The plasma can include a remote plasma source, a microwave plasma, a capacitively coupled plasma, a remote capacitively coupled plasma, a remote inductively coupled plasma, or a combination thereof. An RF power may be supplied to generate and maintain the non-oxidizing plasma in the processing chamber. The RF power may be between about 10 Watts and about 3000 Watts at a frequency in a range of from about 350 KHz to about 100 MHz. The RF power may be applied continuously or may be pulsed.

In embodiments, where operations 304 and 306 are performed concurrently, the first precursor-containing gas mixture and the second precursor-containing gas mixture may be introduced into the processing volume while maintaining a pressure of about 10 mTorr to about 50 Torr and a temperature of about 0° C. to about 200° C. A carrier gas, such as argon (Ar), helium (He), nitrogen (N₂), may be supplied with the first precursor-containing gas mixture and the second precursor-containing gas mixture into the processing volume. The carrier gas may be introduced to the processing chamber at a flow rate of about 100 sccm to about 10,000 sccm.

In embodiments, where operations 304 and 306 are performed concurrently, a ratio of the flow rate of the first flow rate to the second flow rate can be about 1:1 to about 1:30 of the first flow rate to the second flow rate. Without being bound by theory, a ratio of about 1:1 to about 1:30 of the first flow rate to the second flow rate can allow for improved thermal ALD due to the polarization of the surface layer bonds via activation of the silicon atoms of the precursors. For example, a ratio of about 1:1 to about 1:30 of the first flow rate to the second flow rate can increase the polarity of an O—H bond of B—O—Si—O—H, a N-Me bond of B—O—Si—N-Me₂, and/or a Si—Cl bond of B—O—Si—Cl, thereby promoting thermal ALD by preventing self-limiting growth.

At operation 308, the substrate 210 and the dielectric film are subject to a post-deposition process. In some embodiments, operation 308 occurs after the dielectric film formed on the substrate reaches a predetermined thickness, e.g., about 1 Å to about 1000 Å. In some embodiments, operation 308 occurs between cycles of operations 304 and 306 until the dielectric film formed on the substrate reaches a predetermined thickness.

The post-deposition process may include an annealing process, a cure process, or other suitable process. For example, the substrate and the dielectric film can be annealed under vacuum, an inert gas, a hydrocarbon gas, NH₃, or an oxidizing gas. In some embodiments, the dielectric film can be anneals according to a thermal annealing process in the presence of ammonia, water, oxygen, nitrogen, argon, vacuum, or a combination thereof. The thermal annealing process can include a temperature of about 200° C. to about 600° C. The substrate and the dielectric film may additionally undergo an UV cure process under vacuum, an inert gas, a hydrocarbon gas, NH₃, or an oxidizing gas. The UV cure process can include a temperature of about 25° C. to about 600° C.

The post-deposition process may include a plasma post-treatment process. The plasma post-treatment process can include administering a plasma to the low k film using a remote plasma source, a microwave plasma, a capacitively coupled plasma, a remote capacitively coupled plasma, a remote inductively coupled plasma, or a combination thereof. The temperature plasma post-treatment process can include introducing the plasma at a temperature of about 25° C. to about 600° C. Without being bound by theory, the post-deposition process is configured to induce additional cross-linking of the dielectric film, thus improving the mechanical property thereof.

Overall, the present disclosure provides methods of preparing thin, low dielectric constant films from various precursors. In particular, dielectric films of the present disclosure were formulated from boron-containing precursors. It was found that films formed from methods and boron containing precursors disclosed herein exhibit improved allow for w k films having a low dielectric constant (k), e.g., below 3.5, a low wet etch rate in DHF, resistance to ashing plasma, and a thermal stability of greater than 500° C. Advantageously, the low k films, such as SiCON, SiCO, SiO, SiN, SiON, or a combination thereof, can be formed by catalyzing thermal atomic layer deposition (ALD) using boron-containing precursors without increasing the dielectric constant to greater than 4. The boron-containing precursors act as a lewis acid, thereby activating the dielectric films deposited over the substrate to allow for additional thermal ALD reactions between the silicon-containing precursors precursor and one or more surface bonds of the dielectric film.

The phrases, unless otherwise specified, “consists essentially of” and “consisting essentially of” do not exclude the presence of other steps, elements, or materials, whether or not, specifically mentioned in this specification, so long as such steps, elements, or materials, do not affect the basic and novel characteristics of the present disclosure, additionally, they do not exclude impurities and variances normally associated with the elements and materials used.

Numerical ranges used herein include the numbers recited in the range. For example, the numerical range “from 1 wt % to 10 wt %” includes 1 wt % and 10 wt % within the recited range.

For the sake of brevity, only certain ranges are explicitly disclosed herein. However, ranges from any lower limit may be combined with any upper limit to recite a range not explicitly recited, as well as, ranges from any lower limit may be combined with any other lower limit to recite a range not explicitly recited, in the same way, ranges from any upper limit may be combined with any other upper limit to recite a range not explicitly recited. Additionally, within a range includes every point or individual value between its end points even though not explicitly recited. Thus, every point or individual value may serve as its own lower or upper limit combined with any other point or individual value or any other lower or upper limit, to recite a range not explicitly recited.

All numerical values within the detailed description herein are modified by “about” the indicated value, and take into account experimental error and variations that would be expected by a person having ordinary skill in the art.

All documents described herein are incorporated by reference herein, including any priority documents and or testing procedures to the extent they are not inconsistent with this text. As is apparent from the foregoing general description and the specific embodiments, while forms of the present disclosure have been illustrated and described, various modifications can be made without departing from the spirit and scope of the present disclosure. Accordingly, it is not intended that the present disclosure be limited thereby. Likewise, the term “comprising” is considered synonymous with the term “including.” Likewise whenever a composition, an element or a group of elements is preceded with the transitional phrase “comprising,” it is understood that we also contemplate the same composition or group of elements with transitional phrases “consisting essentially of,” “consisting of,” “selected from the group of consisting of,” or “is” preceding the recitation of the composition, element, or elements and vice versa.

While the present disclosure has been described with respect to a number of embodiments and examples, those skilled in the art, having benefit of this disclosure, will appreciate that other embodiments can be devised which do not depart from the scope and spirit of the present disclosure.

What is claimed is:

1. A method of depositing a dielectric film in a processing chamber, the method comprising:
disposing a substrate on a susceptor disposed within a processing chamber;
providing a first precursor-containing gas mixture into the processing chamber, wherein the first precursor-containing gas mixture comprises:
a boron-containing precursor; and
a carrier gas selected from the group consisting of argon, nitrogen, and helium;
providing a second precursor-containing gas mixture into the processing chamber.

2. The method of claim 1, wherein the boron-containing precursor comprises tris(dimethylamino)borane (TDMAB), tris(ethylmethylamino)borane (TEMAB), trimethyl borate, triethyl borate, triisopropyl borate, diborane, borazine, triethylborane, trimethylborane, borane dimethylamine, borane diethylamine, borane trimethylamine, borane triethylamine, borane ammonia, boron trichloride, boron tribromide, boron trifluoride, or a combination thereof.

3. The method of claim 2, wherein the boron-containing precursor comprises trimethyl borate, trimethylborane, or diborane.

4. The method of claim 1, wherein the second precursor-containing gas mixture comprises a silicon-containing precursor gas.

5. The method of claim 4, wherein the silicon-containing precursor gas is represented by formula (I): 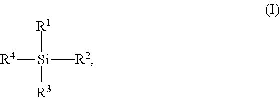
wherein each R¹-R⁴ is independently hydrogen, substituted C₁-C₁₀ alkyl, unsubstituted C₁-C₁₀ alkyl, substituted C₁-C₁₀ alkylene, unsubstituted C₁-C₁₀ alkylene, substituted C₁-C₁₀ alkynylene, unsubstituted C₁-C₁₀ alkynylene, substituted C₁-C₁₀ alkyoxy, unsubstituted C₁-C₁₀ alkyoxy, substituted C₁-C₁₀ alkylamine, unsubstituted C₁-C₁₀ alkylamine, halide, substituted C₁-C₁₀ alkyloxyamine, unsubstituted C₁-C₁₀ alkyloxyamine, substituted C₁-C₁₀ alkyl sulfonamide, or unsubstituted C₁-C₁₀ alkyl sulfonamide.

6. The method of claim 5, wherein each of R¹-R⁴ is independently methyl, methoxy, ethyl, ethoxy, isopropyl, isoproproxy, or tert-butyl.

7. The method of claim 4, wherein the silicon-containing precursor gas is represented by formula (II): 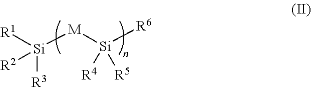
wherein M is carbon or oxygen;
n is an integer of 1 to 5; and
each R¹-R⁶ is independently hydrogen, substituted C₁-C₁₀ alkyl, unsubstituted C₁-C₁₀ alkyl, substituted C₁-C₁₀ alkylene, unsubstituted C₁-C₁₀ alkylene, substituted C₁-C₁₀ alkynylene, unsubstituted C₁-C₁₀ alkynylene, substituted C₁-C₁₀ alkyoxy, unsubstituted C₁-C₁₀ alkyoxy, substituted C₁-C₁₀ alkylamine, unsubstituted C₁-C₁₀ alkylamine, halide, substituted C₁-C₁₀ alkyloxyamine, unsubstituted C₁-C₁₀ alkyloxyamine, substituted C₁-C₁₀ alkyl sulfonamide, or unsubstituted C₁-C₁₀ alkyl sulfonamide.

8. The method of claim 7, wherein each of R¹-R⁶ is independently substituted C₁-C₁₀ alkylamine or unsubstituted C₁-C₁₀ alkylamine.

9. The method of claim 1, wherein a first flow rate of the first precursor-containing gas mixture is about 50 sccm to about 10,000 sccm.

10. The method of claim 9, wherein a second flow rate of the second precursor-containing gas mixture may be between about 50 sccm to about 10,000 sccm.

11. The method of claim 10, wherein a ratio of the first flow rate to the second flow rate is about 1:1 to about 1:30 of the first flow rate to the second flow rate.

12. The method of claim 1, wherein providing the first precursor-containing gas mixture into the processing chamber comprises:
performing a first purge process;
introducing a first co-reactant to the processing chamber; and
performing a second purge process.

13. The method of claim 12, wherein the first co-reactant comprises water, ammonia, primary alcohols, secondary alcohols, carboxylic acids, aldehydes, hydrazines, or alkyl amines.

14. The method of claim 12, wherein providing the second precursor-containing gas mixture into the processing chamber comprises:
performing a third purge process;
introducing a second co-reactant to the processing chamber; and
performing a second purge process.

15. The method of claim 14, wherein the second co-reactant comprises water, ammonia, primary alcohols, secondary alcohols, carboxylic acids, aldehydes, hydrazines, alkyl amines, or a combination thereof.

16. A method of depositing a dielectric film in a processing chamber, the method comprising:
disposing a substrate on a susceptor disposed within a processing chamber; and
providing a first precursor-containing gas mixture and a second precursor-containing gas mixture into the processing chamber in the presence of a plasma, wherein the first precursor-containing gas mixture comprises a boron-containing precursor and the second precursor-containing gas mixture comprises a silicon-containing precursor gas.

17. The method of claim 16, wherein the plasma is a non-oxidizing plasma selected from the group consisting of an argon-based plasma, a nitrogen-based plasma, a helium-based plasma, an ammonium-based plasma, and a hydrogen-based plasma.

18. The method of claim 16, wherein providing the first precursor-containing gas mixture the second precursor-containing gas mixture comprises providing the first precursor-containing gas mixture at a first flow rate and the second precursor-containing gas mixture at a second flow rate, wherein a ratio of the first flow rate to the second flow rate is about 1:1 to about 1:30.

19. A method of depositing a dielectric film in a processing chamber, the method comprising:
disposing a substrate on a susceptor disposed within a processing chamber;
providing a first precursor-containing gas mixture into the processing chamber at a first flow rate, wherein the first precursor-containing gas mixture comprises:
trimethyl borate, trimethylborane, or diborane; and
a carrier gas selected from the group consisting of argon, nitrogen, and helium; and
providing a second precursor-containing gas mixture into the processing chamber at a second flow rate, wherein a ratio of the first flow rate to the second flow rate is about 1:1 to about 1:30.

20. The method of claim 19, wherein the second precursor-containing gas mixture comprises a silicon-containing precursor gas.
